(19) United States
(12) Patent Application Publication
(10) Pub. No.: US 2013/0026892 A1
(43) Pub. Date: Jan. 31, 2013

(54) Variable Position Supporting Channel For Computing Equipment Rack

(71) Applicant: Joel Wineland, Garden Ridge, TX (US)

(72) Inventor: Joel Wineland, Garden Ridge, TX (US)

(21) Appl. No.: 13/190,554

(22) Filed: Jul. 26, 2011

(51) Int. Cl. H05K 7/18; H05K 5/02

(52) U.S. Cl. 312/223.2; 211/26

(57) ABSTRACT

In one embodiment, the present invention includes an apparatus having a first support member adapted to a first side of a server rack and a second support member adapted to a second side of the server rack. These support members may each include channels configured along the corresponding support member, which may be implemented as recesses within the support members. These channels are configured to support a rack-mounted enclosure such that multiple channels enable multiple rack-mounted enclosures, some of which can be of variable heights, to be incorporated within the server rack.

### BACKGROUND

Many server computers are configured in a rack systems. More specifically, server racks can include many different servers and other computing equipment as is common in various data center designs. Certain rack systems provide for insertion and removal of a chassis or other rack-mounted enclosure via a sliding rail mechanism, such that telescoping, e.g., ball bearing rails are adapted to the server rack enclosure, and corresponding rail slides are configured on the chassis or other rack-mounted equipment. However, by providing these rails and rail slides, costs can increase. Furthermore, when used in an organization that does not typically perform maintenance or other manual operations on servers while in place in the rack, the flexibility provided by such rails is generally not needed. And, installation is typically more complex with such rails present.

Accordingly, new rack systems have been designed that do away with these rail mechanisms. Instead, a partial static shelf system is provided in which a partial shelf extends inwardly from either the rack sides themselves, or support enclosures within the racks. Accordingly, in these configurations chassis or other enclosures simply slide along and are supported by these partial shelves. However, due to the fabrication of such slides, which are typically formed with shelves having a standard set vertical distance between them, it is impossible to customize inclusion of anything other than a standard size chassis or other enclosure within this partial rack system. One such example of this partial static shelf system is shown in the recently published Facebook Open Compute Project, available at http://opencompute.org.

### SUMMARY OF THE INVENTION

According to one aspect, the present invention includes apparatus for supporting data center equipment. In one embodiment, the apparatus can include support members adapted to opposite sides of a server rack. Each support member can include channels configured along the corresponding support member. By way of corresponding channels of the support members a rack-mounted enclosure adapted within the server rack can be supported. At least one of the channels of the support members can be configured at a varying distance with respect to a spacing between others of the channels to accommodate differently sized equipment, such as rack-mounted enclosures having different heights. As these channels do not extend inwardly within an opening of the server rack, sets of the channels can be unused, yet not impede insertion of rack-mounted enclosures. As one example, a rack-mounted enclosure can include a chassis having mating elements on a bottom thereof to traverse along a first pair of channels of the support members and second mating elements extending from sides of the chassis to traverse along a second pair of the channels.

Another aspect of the present invention is directed to a system having a rack enclosure, support members, and one or more rack-mounted enclosures. The support members can be adapted to sides of the rack enclosure, and can include multiple vertical protrusion members each having channels vertically arranged along the corresponding vertical protrusion member. One first rack-mounted enclosure can be supported by a first set of the channels of the support members, where the enclosure extends vertically adjacent to at least a second set of the plurality of channels of the first and second support members that is unused. A second rack-mounted enclosure can be supported by a third set of the channels of the support members, and a third rack-mounted enclosure can be supported by a fourth set of the channels of the support members, where the fourth set of the channels is directly adjacent in a vertical direction to the third set of the channels. Note that it is possible for the first rack-mounted enclosure to include multiple pairs of mating elements to be supported by the sets of the channels.

Yet another aspect of the present invention is directed to an apparatus having multiple support members adapted to a first side of a server rack, and multiple support members adapted to another side of the server rack. Each of these support members can include channels configured along the corresponding support member. These channels can be configured to support a rack-mounted enclosure within the server rack.

### BRIEF DESCRIPTION OF THE DRAWINGS

FIG. 1 is an overview of a support member in accordance with an embodiment of the present invention.

FIG. 2 is an example of support members in accordance with another embodiment of the present invention.

FIG. 3 is another example of support members in accordance with another embodiment of the present invention.

FIG. 4 is a front view of a populated rack system in accordance with an embodiment of the present invention.

FIG. 5 is a close-up view of a portion of a rack-mounted enclosure being inserted into a channel in accordance with an embodiment of the present invention.

### DETAILED DESCRIPTION

In various embodiments, a support mechanism for supporting rack-mounted servers or other rack-mounted equipment can be realized by providing channels, recesses, or dadoes within a support member such that the rack-mounted components can easily slide horizontally within corresponding channels. Furthermore, by the presence of multiple such channels located vertically within the support mechanism, rack-mounted components of varying heights can be accommodated in a single rack. As such, components of varying heights (e.g., in rack units (U)) can be configured within a differently configured partial static shelf system. Such partial static shelf systems may realize cost reductions, manufacturing simplification and ease of installation. As will be discussed further below, different manners of implementing a channel structure within a support member can occur in different embodiments. And the support member or members can be adapted within a rack or other structure to provide a mechanism for mounting the servers or other devices.

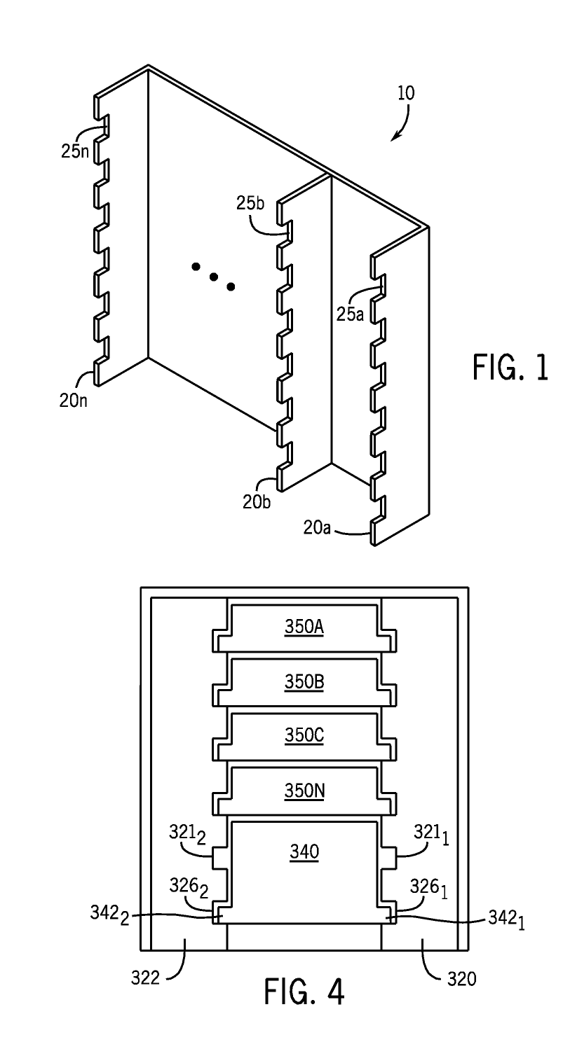

Referring now to FIG. 1, shown is an overview of a support member in accordance with an embodiment of the present invention. As shown in FIG. 1, a support member 10 may be cast, cut, or molded from any suitable rigid material, e.g., of a sheet metal such as a sheet formed of cold rolled steel. Although not shown for ease of illustration in FIG. 1, understand that support member 10 may be configured within a server rack, e.g., affixed to one side of the rack enclosure by means of multiple fasteners on top and bottom portions of the member. A corresponding support member may be configured on the other side of the rack enclosure to thus provide a pair of support members that can accommodate various equipment.

As seen in FIG. 1, support member 10 may include a plurality of columns or protrusion members 20a-20n (generally protrusion member 20, which can be formed from a roll former). The number of such protrusions can vary in different embodiments. However, in a standard rack, at least two such protrusion members may be present and in other embodiments, between 5 and 10 protrusion members may be provided per support member. Additional protrusion members can provide for greater support capabilities, e.g., depending on a weight of the rack-mounted equipment to be supported.

As seen, each of protrusion members 20 includes a plurality of channels, one of which is enumerated in each of the protrusion members, namely channels 25a-25n. The number of channels provided in each protrusion member may be the same, and can vary in different embodiments. Furthermore, understand that the plurality of channels can be provided at a fixed vertical spacing, or the spacing between channels can vary. However, the corresponding channels of each of the protrusion members may be at the same height to provide for ease of insertion/removal of a corresponding piece of rack-mounted equipment. As one example, there may be one channel per U (i.e., 1.75 inches) of height of the protrusion members.

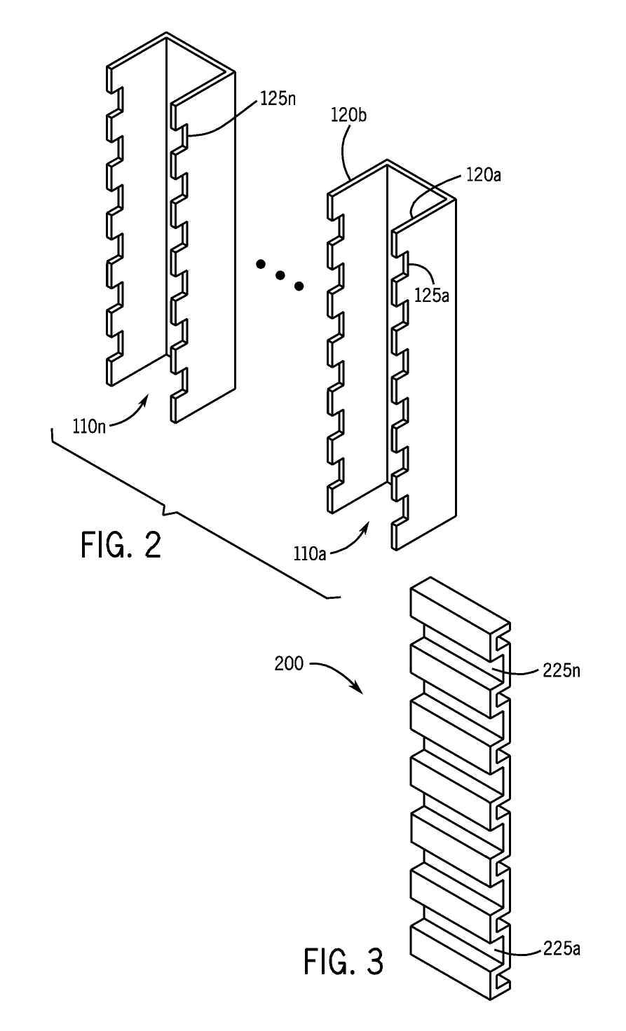

Although support member 10 can be formed from a single sheet of rolled steel, the scope of the present invention is not limited in this regard and different implementations are possible. For example, instead of being formed from a single piece or sheet of material, multiple support members can be provided for each side of a rack. Specifically referring now to FIG. 2, shown is an example of support members in accordance with another embodiment of the present invention. As shown in the embodiment of FIG. 2, a plurality of support members 110a-110n may be present. For example, in one embodiment three such structures may be present, e.g., at a front, middle, and rear portion of a rack, on each side of the rack. As seen, each of these support members includes a plurality of channels, representative channels 125a-125n are enumerated in FIG. 2. Any desired number of these multiple support members, each of which includes a pair of protrusion members 120a and 120b, can be provided in a given implementation. As one example, two such support members 110 can be provided on each side of a rack, however the scope of the present invention is not so limited and in other embodiments more than two, e.g., 3 or 4 different support members can be provided on each side of the rack. In the embodiments of FIGS. 1 and 2, the channels can be formed by a cutting operation such as via a mitering tool. As an example, the channels may be on the order of approximately 0.5 inches in height (in a vertical direction), and approximately 0.25 to 0.5 inches deep (in a lateral direction) and can be spaced apart vertically at regular vertical increments, e.g., every 1.75 inches.

Still other implementations of support members can be realized in additional embodiments. For example, with reference now to FIG. 3, shown is another support member 200. As seen in the embodiment of FIG. 3, support member 200 may be one of multiple support members that can be adapted on either side of a rack, e.g., at front and rear portions. Each support member can be formed from a single sheet of material, e.g., rolled steel that is formed with a roll former and may take a generally serpentine form such that a plurality of channels 225a-225n are formed within the support member itself. Note that this support member may have a relatively small width (in a horizontal direction), such that at least two members can be configured on each side, with corresponding support members configured on the opposite side of a rack to enable the installation and support of rack-mounted components within the corresponding channels of the support members.

As discussed above, in various embodiments a rack can easily accommodate rack-mounted enclosures of differing sizes without requiring a custom-designed shelf system. Referring now to FIG. 4, shown is a front view of a populated rack system in accordance with an embodiment of the present invention. As shown in FIG. 4, rack 300 may include various rack-mounted enclosures that can be slidably inserted into (in a horizontal direction, into the page in FIG. 4) and supported by a corresponding channel. As seen, a first enclosure 340 may be of a custom height, e.g., two or more U, and multiple rack-mounted enclosures 350a-350n may be present, which in an embodiment can be of a standard height, e.g., 1 U. These rack-mounted enclosures each may support one or more server boards, expansion cards and related equipment such as storage, networking equipment and so forth.

As further seen in FIG. 4, a first pair of channels of support members 320-322, namely channels 326₁ and 326₂ may receive corresponding mating elements 342₁ and 342₂ of rack-mounted enclosure 340. Note that in the embodiment of FIG. 4, these mating elements are located on the bottom portion of the rack-mounted enclosure. In contrast, conventional enclosures typically include a mating element on a top side of the enclosure to mate with a partial shelf structure extending into the rack enclosure. And here, the channels do not extend into an open portion of the rack enclosure.

By placing the mating elements on a bottom portion of the enclosure, ease of manufacture, installation and maintenance can be realized. Furthermore, to provide greater support for heavy equipment, multiple mating elements can be provided on the enclosure, each to mate with a different pair of the channels. For example, mating elements can be provided at a 1 U distance to enable mating with corresponding channels. Although the enclosure is shown in FIG. 4 with integral mating elements, in other embodiments mating elements can be adapted to an enclosure, such as by bolting or via another fastening means.

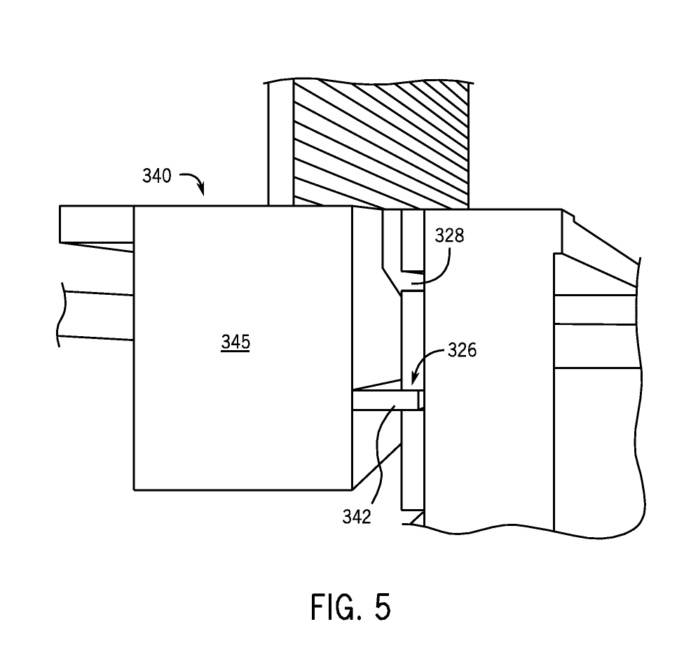

With quick reference now to FIG. 5, shown is a close-up view of a portion of a rack-mounted enclosure being inserted into a channel in accordance with an embodiment of the present invention. As seen, enclosure 340 includes mating element 342 configured at a bottom portion of chassis 345 to mate with and slidably insert into channel 326. And as seen, due to the size of enclosure 340 a second channel 328 is unused.

With reference back to FIG. 4, note that due to the larger size of rack-mounted enclosure 340, a second pair of channels 321₁ and 321₂ may be unused. Although only a single pair of unused channels is shown in the illustration of FIG. 4, understand that in different implementations multiple unused channels may be present due to the installation of a larger rack-mounted enclosure. In contrast, with a conventional partial shelf system, no variable-sized equipment can be inserted due to the regular presence of partial shelves along the entire vertical height of the rack enclosure. Instead in a conventional partial shelf system protrusions or shelves are defined at fixed intervals and are static—generally they cannot be reconfigured without removal of all equipment and replacement of the enclosure/partial shelf framework with one of alternate disposition. Thus the only ability to accommodate larger height equipment would be by a custom design. In a more conventional server cabinet rail slides or supports are used and attached to individual chassis with corresponding rails within the cabinet. Although these may be removed individually and reoriented to accommodate alternate equipment profiles, it can be a time-consuming, labor-intensive and possibly difficult operation.

Referring back to FIG. 4, note that the additional rack-mounted enclosures 350a-350n each may be implemented within a pair of channels. Although only a few such enclosures are shown for ease of illustration in the embodiment of FIG. 4, understand the scope of the present invention is not limited in this manner and more or fewer enclosures may be included. Furthermore, enclosures of varying heights from larger than conventional size to smaller than conventional size can be accommodated. Note that while FIG. 4 shows that the mating elements are included as part of the enclosures, e.g., the chassis itself, embodiments are not limited in this regard. In another embodiment a mating element can be affixed to a corresponding enclosure or chassis.

Thus by providing a channel, recess, inset slot, or dado at varying vertical intervals within a support member, equipment of variable heights can be inserted into any available opening, without regard to dimensions of other installed elements, and also without regard to the presence of other channels that may be present within a location of the height of the rack-mounted enclosure. And as a result, equipment of varying heights can be accommodated by way of the multiple channels present in the support members. Thus in contrast to a conventional partial rolled shelf system in which the partial shelves protrude into the open space of the rack, here the channels or dadoes provide for an entirely open space within the rack to enable support of larger equipment.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. An apparatus comprising:
a first support member adapted to a first side of a server rack and a second support member adapted to a second side of the server rack;
wherein the first support member and the second support member each include a plurality of channels configured along the corresponding support member, wherein a first channel of the first support member and a first channel of the second support member are configured to support a rack-mounted enclosure.

2. The apparatus of claim 1, wherein at least one of the plurality of channels of each of the first and second support members is configured at a varying distance with respect to a spacing between others of the plurality of channels.

3. The apparatus of claim 1, further comprising a plurality of rack-mounted enclosures, at least one having a different height, supported by corresponding pairs of the plurality of channels.

4. The apparatus of claim 3, wherein the rack-mounted enclosure having the different height is supported by a first pair of the plurality of channels and extends vertically above at least one other pair of the plurality of channels.

5. The apparatus of claim 4, wherein the at least one other pair of the plurality of channels is unused.

6. The apparatus of claim 3, wherein the rack-mounted enclosure includes a first pair of mounting elements to be supported by the first pair of the plurality of channels and a second pair of mounting elements to be supported by a second pair of the plurality of channels.

7. The apparatus of claim 1, wherein the first and second support members each include a plurality of vertical protrusion members extending from the corresponding support member each at a different horizontal location of the server rack, each of the plurality of vertical protrusion members having a plurality of channels.

8. The apparatus of claim 7, wherein the rack-mounted enclosure is supported by corresponding pairs of the plurality of channels of the corresponding vertical protrusion members of the first and second support members.

9. The apparatus of claim 1, wherein the first support member is formed from a single sheet having a generally serpentine shape to form the plurality of channels.

10. The apparatus of claim 1, wherein the first support member is formed of a plurality of members each including a plurality of channels and adapted to the first side of the server rack.

11. The apparatus of claim 1, wherein the rack-mounted enclosure includes a chassis having mating elements on a bottom thereof to traverse along a first pair of the plurality of channels of the first and second support members.

12. The apparatus of claim 11, wherein the chassis includes second mating elements extending from a first side and a second side thereof to traverse along a second pair of the plurality of channels of the first and second support members.

13. The apparatus of claim 1, wherein the plurality of channels do not extend into an open portion of the server rack.

14. A system comprising:
a rack enclosure;
a first support member adapted to a first side of the rack enclosure, the first support member including a plurality of vertical protrusion members each including a plurality of channels vertically arranged along the corresponding vertical protrusion member;
a second support member adapted to a second side of the rack enclosure, the second support member including a plurality of vertical protrusion members each including a plurality of channels vertically arranged along the corresponding vertical protrusion member;
a first rack-mounted enclosure supported by a first set of the plurality of channels of the first and second support members, wherein the first rack-mounted enclosure extends vertically adjacent to at least a second set of the plurality of channels of the first and second support members that is unused;
a second rack-mounted enclosure supported by a third set of the plurality of channels of the first and second support members; and
a third rack-mounted enclosure supported by a fourth set of the plurality of channels of the first and second support members, wherein the fourth set of the plurality of channels is directly adjacent in a vertical direction to the third set of the plurality of channels.

15. The system of claim 14, wherein the third set of the plurality of channels is directly adjacent in a vertical direction to the second set of the plurality of channels.

16. The system of claim 14, wherein the first rack-mounted enclosure includes a first pair of mating elements to be supported by the first set of the plurality of channels and a second pair of mating elements to be supported by another set of the plurality of channels.

17. The system of claim 14, wherein the first support member includes a first set of support members each including a pair of the vertical protrusion members.

18. The system of claim 14, wherein the second rack-mounted enclosure includes mating elements on a bottom thereof to traverse along the third set of the plurality of channels.

19. An apparatus comprising:
a first support member and a second support member adapted to a first side of a server rack, wherein the first support member and the second support member each include a plurality of channels configured along the corresponding support member, wherein a first channel of the first support member and a first channel of the second support member are configured to support a rack-mounted enclosure on the first side of the server rack; and
a third support member and a fourth support member adapted to a second side of the server rack, wherein the third support member and the fourth support member each include a plurality of channels configured along the corresponding support member, wherein a first channel of the third support member and a first channel of the fourth support member are configured to support the rack-mounted enclosure on the second side of the server rack.

20. The apparatus of claim 19, further comprising a first rack-mounted enclosure supported by the first channels, wherein the first rack-mounted enclosure extends vertically adjacent to at least the second channels.

21. The apparatus of claim 20, wherein the first rack-mounted enclosure includes first mating elements on a bottom thereof to traverse along the first channels and second mating elements to traverse along the second channels.
